(19) United States
(12) Patent Application Publication
(10) Pub. No.: US 2001/0052092 A1
(43) Pub. Date: Dec. 13, 2001

(54) Reading defect detecting circuit and reading defect detecting method of EEPROM

(75) Inventor: Rumi Matsushita, Kanagawa (JP)

Correspondence Address: HELFGOTT & KARAS, P.C., 60th FLOOR, EMPIRE STATE BUILDING, NEW YORK, NY, 10118, US

(73) Assignee: NEC CORPORATION

(21) Appl. No.: 09/730,940

(22) Filed: Dec. 6, 2000

(30) Foreign Application Priority Data
Dec. 6, 1999 (JP) 11-346972

(51) Int. Cl. G11C 7/00; G06F 7/02; G11C 29/00; H03M 13/00

(52) U.S. Cl. 714/719; 714/819; 365/200

(57) ABSTRACT

A reading defect detecting circuit of EEPROM is provided. An ordinary read voltage generating circuit generates a read voltage V1, and a defect detecting read voltage generating circuit generates a defect detecting read voltage V2 which is slightly higher than the voltage V1. A selector selects the voltage V1 or V2 to apply it to a FLASH EEPROM, and the data are read out from a FLASH EEPROM. Both data being readout at voltage V1 and voltage V2 are compared in a comparator. If the data are not matched, an error flag is generated in the comparator, and it is used as an interrupt signal, thereby the CPU recognizes the error. The mismatched address and correct data at this address are read out, and thereby the correct data is written again at the mismatched address.

### BACKGROUND OF THE INVENTION

1. Field of the Invention

The present invention relates to a reading defect detecting circuit and a reading defect detecting method of EEPROM which is an electrically erasable programmable nonvolatile semiconductor memory device, and more particularly to a reading defect detecting circuit and a reading defect detecting method of EEPROM capable of avoiding malfunction of EEPROM due to drop of threshold voltage.

2. Description of the Related Art

Generally, a FLASH EEPROM (electrically erasable programmable read only memory), in the case of reading data, reads “1” when the threshold voltage of a selected memory cell is lower than read voltage V1, and reads “0” when higher than read voltage V1. However, if the threshold voltage of the EEPROM cell changes with the passing of the time, the microcomputer may malfunction.

For example, in a memory transistor having a floating gate, if the semiconductor chip is used for a long time by the user after writing the data, an electric field is caused in the insulating film enclosing the floating gate, or if the semiconductor chip is used in high temperature state, electrons accumulated in the floating gate are excited, and therefore the electrons accumulated in the floating gate are released on a silicon substrate on which the control gate or element is formed, thereby lowering the threshold voltage.

Thus, the threshold voltage of the memory cell in which the data is written may become lower than read voltage V1, and in such a case data may be read as “1” instead of the expected value of “0”, and the computer malfunctions.

Among conventional microcomputers incorporating the EEPROM, a microcomputer is proposed to screen reading defects due to changes of threshold voltage by using a PROM writer (Japanese Patent Application Laid-open No. 7-14393). According to this publication, if the operating power source voltage is low, the threshold voltage of the EEPROM cell is changed due to fluctuation of supply voltage and temperature, and the microcomputer may malfunction. However, since the threshold voltage of EEPROM cell is a relative value to the reference potential of the control gate, by varying this reference value, the apparent threshold value of the EEPROM can be changed. Therefore, it is designed to select reference potential V3 in usual reading, and to select reference potential V4 which is set to be a threshold voltage varying depending on the supply voltage or temperature when comparing data after writing action by the EEPROM writer. Thus, the apparent threshold voltage after writing action can be changed. As a result, the EEPROM cell judged to be conforming when comparing after the writing action does not cause reading defect in usual reading state.

However, this technique of screening the defect by using the conventional EEPROM writer requires execution data comparison process in order to detect defective EEPROM cell after writing action by the writer.

### SUMMARY OF THE INVENTION

It is an object of the invention to provide a reading defect detecting circuit and a reading defect detecting method of EEPROM capable of avoiding malfunction of microcomputer before the threshold voltage drops lower than the reading voltage in operation of memory cell of EEPROM.

The reading defect detecting circuit of EEPROM according to the present invention comprises an ordinary read voltage generating circuit for generating a voltage to be used in ordinary reading of EEPROM which is the object of detection, a defect detecting read voltage generating circuit for generating a defect detecting read voltage which is higher than the ordinary read voltage, a selector for selecting a voltage to be applied to the EEPROM from the ordinary read voltage and defect detecting read voltage, a control circuit for controlling the selection timing of this selector, and a comparator for comparing first data and second data being read out by the EEPROM from the ordinary read voltage and defect detecting read voltage respectively selected by the selector.

In the invention, the defect detecting read voltage is higher than the ordinary read voltage, and the data being read out from the ordinary read voltage and defect detecting read voltage are compared in the comparator. As a result, if the data are not matched, it is recognized that the data being read out from the ordinary read voltage is correct, while the data being read out from the higher defect defecting read voltage is wrong, and at the addresses of these data, it is possible to detect preliminarily the possibility of malfunction of EEPROM due to drop of threshold voltage.

The comparator may also include an error flag generating circuit for generating an error flag when the first data and second data are not matched.

Further, the comparator may also include a data latch circuit and an address latch circuit for storing respectively the first data and the address of the first data in the EEPROM.

The reading defect detecting circuit of EEPROM may be designed to repeat a period comprising at least a first timing for selecting the ordinary read voltage by the selector, a second timing for selecting the defect detecting read voltage by the selector, and a third timing for comparing the first and second data by the comparator.

The reading defect detecting method of EEPROM of the invention comprises the steps of reading out first data and second data respectively by applying an ordinary read voltage used as ordinary read voltage of EEPROM to be detected and a defect detecting read voltage higher than this ordinary read voltage sequentially into the EEPROM, comparing the first data and second data, and generating an error flag when the first data and second data are not matched at the comparing step.

In the invention, by comparing the data of EEPROM being read out from the ordinary read voltage and the defect detecting read voltage of higher voltage than the former during operation of the microcomputer, if the data are not matched, the data being readout from the defect detecting read voltage is judged to be wrong, and decline of threshold voltage in the written memory cell is recognized. Hence, malfunction of the microcomputer due to reading of wrong data can be avoided.

After an error flag is generated, the first data may be written at the address in the EEPROM from which the first data and second data are read out. By holding the mismatched data and their addresses, if a defect is detected, by reading out the mismatched addresses and correct data of these addresses, correct data can be written again so that the threshold voltage may be raised.

### BRIEF DESCRIPTION OF THE DRAWINGS

FIG. 1 is a block diagram showing a reading defect detecting circuit of EEPROM in an embodiment of the invention.

FIG. 2 is a block diagram showing a comparator of the reading defect detecting circuit of EEPROM in the embodiment of the invention.

FIG. 3 is a graph showing time-course changes of threshold voltage in the EEPROM in the embodiment of the invention.

FIG. 4 is a timing clock diagram of the reading defect detecting circuit of EEPROM in the embodiment of the invention.

### DESCRIPTION OF THE PREFERRED EMBODIMENT

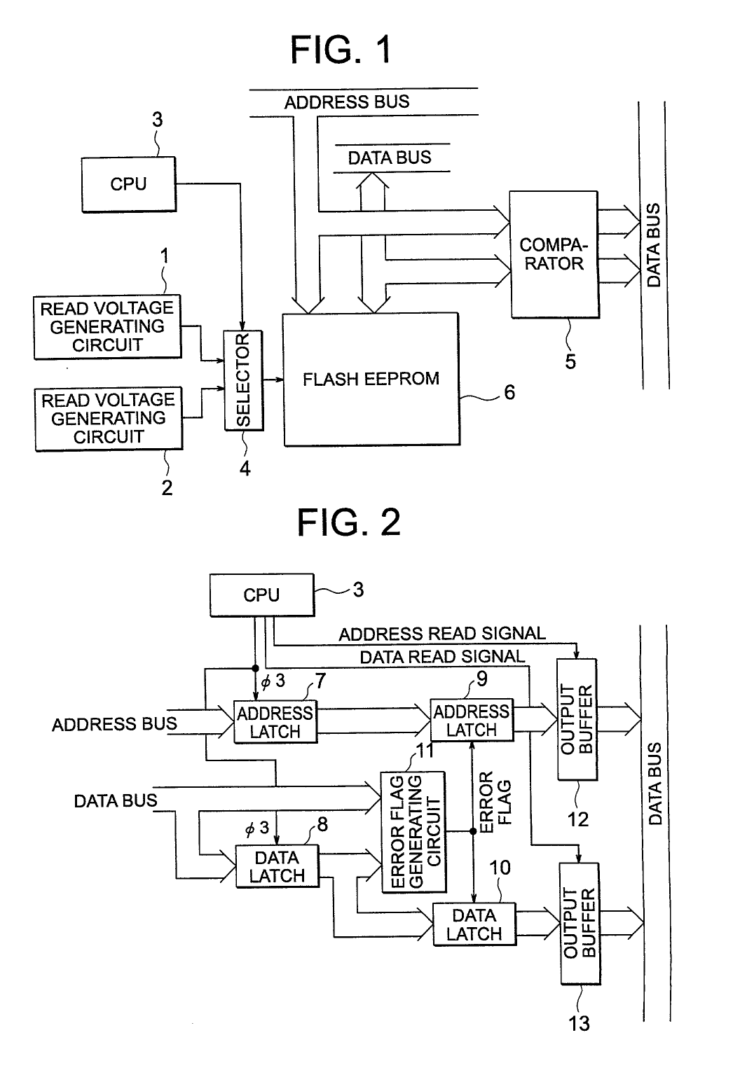

A preferred embodiment of the invention is described specifically below with referring to the accompanying drawings. FIG. 1 is a block diagram showing a configuration of a reading defect detecting circuit of EEPROM in an embodiment of the invention. As shown in FIG. 1, in the reading defect detecting circuit of EEPROM of the embodiment comprises an ordinary read voltage generating circuit 1, a defect detecting read voltage generating circuit 2, a selector 4, a CPU 3, and a comparator 5. A microcomputer comprises the reading defect detecting circuit of EEPROM and FLASH EEPROM 6. A read voltage generating circuit 1 generates a read voltage of a FLASH EEPROM 6 used ordinarily (hereinafter called ordinary read voltage) V1, and feeds into a selector 4. A read voltage generating circuit 2 generates a defect detecting read voltage V2 slightly higher than the ordinary read voltage V1, and feeds into the selector 4. The selector 4, receiving a timing control signal from a CPU (central processing unit: microprocessor) 3, and alternately selects the ordinary read voltage V1 or defect detecting read voltage V2. The voltage V1 or V2 selected by the selector 4 is put into the FLASH EEPROM 6. When the ordinary read voltage V1 is put into the FLASH EEPROM 6, data R1 is read out. When the defect detecting read voltage V2 is put in, data R2 is read out, and they are sent out into data bus. The address data of data R1 and R2 are also sent out into the address bus, and the data R1 and R2 and their addresses are put into a comparator 5. The comparator 5 compares data R1 and data R2. When data R1 and data R2 are not matched, the addresses of the mismatched data and correct data of the address, that is, data R1 are sent out into the data bus.

The comparator 5 is explained in detail below. FIG. 2 is a block diagram showing the inside of the comparator 5. As shown in FIG. 2, in the comparator 5, the address bus is connected to an address latch circuit 7. The address latch circuit 7 latches the data of the address at the timing of the CPU 3. The data bus is connected to a data latch circuit 8 and an error flag generating circuit 11. Further, the data latch circuit 8 is connected to the error flag generating circuit 11 and data latch circuit 10 by data bus. The data latch circuit 8 latches data R1 at the timing of the CPU 3. Data R2 is put into the error flag generating circuit 11, and data R1 is entered from the data latch circuit 8. The error flag generating circuit 11 compares data R1 and data R2, and generates an error flag when the both are judged to be mismatched. The error flag thus generated in the error flag generating circuit 11 is put into the CPU 3, address latch circuit 9, and data latch circuit 10. The address latch circuit 7 is connected to an address latch circuit 9 through the address bus. By the timing of the error flag entered in the address latch circuit 9, the mismatched address data is stored in the address latch circuit 9 from the address latch circuit 7. Further, by the timing of the error flag entered in the data latch circuit 10, the data R1 of the address being mismatched is stored in the data latch circuit 10 from the data latch circuit 8. The address latch circuit 9 and data latch circuit 10 are respectively connected to an output buffer 12 and an output buffer 13 through the address bus and data bus. By the timing of the error flag entering the CPU 3, the address read signal and data read signal are respectively put into the output buffer 12 and output buffer 13 from the CPU 3. The output buffer 12 receives the mismatched address stored in the address latch circuit 9, by the address read signal of the CPU 3, and issues it to the data bus. Similarly, the output buffer 13 receives the data R1 of the mismatched address stored in the data latch 10, by the data read signal of the CPU 3, and issues it to the data bus.

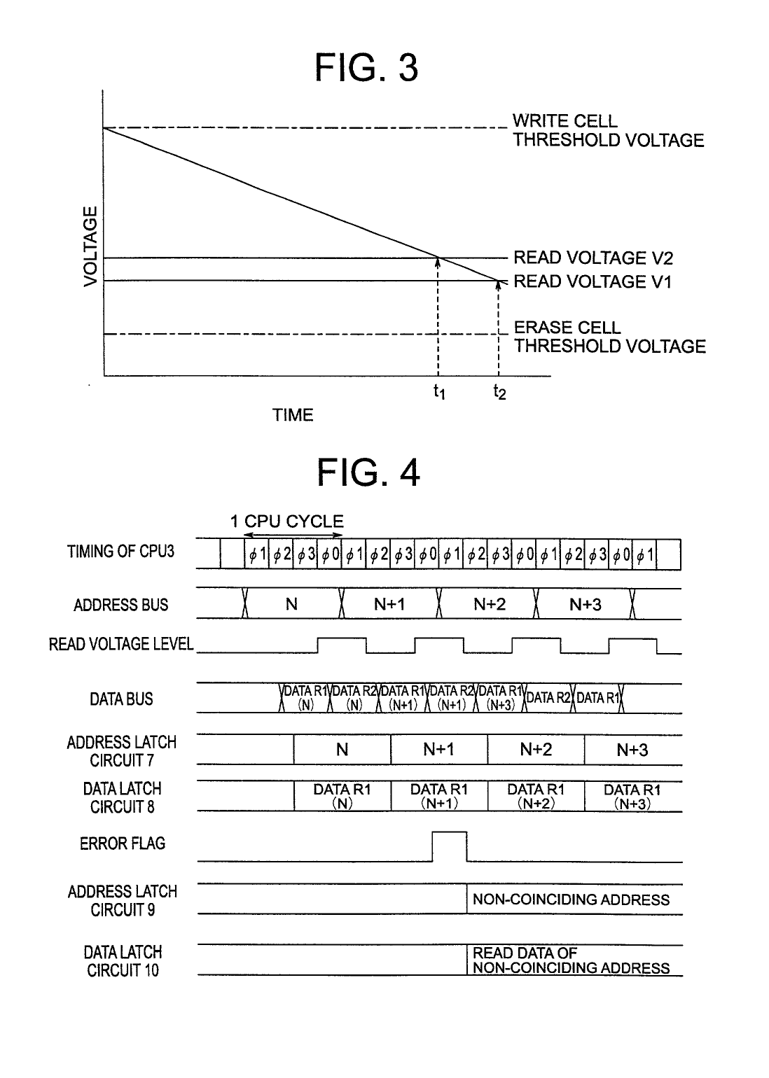

In the reading defect detecting circuit of EEPROM having such configuration, the reason why it has the ordinary read voltage V1 and defect detecting read voltage V2 is explained in detail below. As mentioned above, the reading defect detecting circuit of EEPROM incorporating the EEPROM malfunctions when the threshold voltage declines. FIG. 3 is a graph showing time-course changes of the threshold voltage in the EEPROM cell. As shown in FIG. 3, the threshold voltage of the EEPROM declines from the writing cell threshold voltage at the time of writing with the passing of the time, and at time t2, it is lower than the ordinary read voltage V1. Therefore, when it is read at the ordinary read voltage V1, “0” is read same as the expected value up to time t2, but after time t2, it is read as “1” by mistake instead of expected value of “0”, and the microcomputer malfunctions. At time t1, on the other hand, since the ordinary read voltage V1 is larger than the threshold voltage, “0” is read same as the expected value. Herein, if read out at the defect detecting read voltage V2 slightly higher than the ordinary read voltage V1, after time t1, “1” is read out by mistake instead of the expected value of “0”. That is, the data is read by mistake earlier than time t2 when the microcomputer begins to malfunction, so that lowering of threshold value can be recognized beforehand. The invention comprises the comparator 5 for comparing the signals of the defect detecting read voltage V2 and ordinary read voltage V1, and is intended to detect read error by the CPU 3 itself by making use of the phenomenon that the defect detecting read voltage V2 slightly higher than the ordinary read voltage V1 reads out a wrong signal beforehand.

The operation of the embodiment is explained. FIG. 4 is a timing clock diagram of the reading defect detecting circuit of EEPROM of the embodiment. As shown in FIG. 1 and FIG. 4, the read voltage generating circuit 1 generates an ordinary read voltage V1. The defect detecting read voltage generating circuit 2 generates a defect detecting read voltage V2 slightly higher than the ordinary read voltage V1. The CPU 3 has a timing clock of which one cycle is composed of φ1, φ2, φ3, and φ0, and by the selector 4 which is a changeover circuit of this timing clock, the read voltage level is changed over at the timing of φ2 and φ0. At the timing of φ2 of the CPU 3, the ordinary read voltage V1 is put into the FLASH EEPROM 6, and at the timing of φ0, the defect detecting read voltage V2 is put into the FLASH EEPROM 6. By the ordinary read voltage V2 or defect detecting read voltage V2 selected by this selector 4, the data is read out from the FLASH EEPROM 6 into the data bus. Therefore, In the data bus, the data R1 and data R2 are readout at the timing of φ2 and φ0 in every one cycle (N, N+1, N+2, . . . ). The address of the data being read out at this time is also read out into the address bus in every one cycle. The data R1 being read out at the ordinary read voltage V1 and the data R2 being read out at the defect detecting read voltage V2 are put into the comparator 5 together with the addresses of data R1 and data R2.

As shown in FIG. 2 and FIG. 4, in the comparator 5, the addresses of the data R1 and data R2 being read out from the FLASH EEPROM 6 are taken into the address latch circuit 7 at the timing of φ3. The data R1 being read out from the FLASH EEPROM 6 at the ordinary read voltage V1 is taken into the data latch circuit 8 at the timing of φ3, and is then put into the error flag generating circuit 11. It is compared with the data R2 being read out from the FLASH EEPROM 6 at the defect detecting read voltage V2, in the error generating circuit 11. The comparator 5 sets up an error flag when the data R1 and data R2 are judged to be mismatched. That is, as mentioned above, when the data is read out at the defect detecting read voltage V2, since the defect detecting read voltage V2 is higher than the ordinary read voltage V1, it exceeds the threshold voltage, and wrong data is read out. In this embodiment, at N+1 cycle shown in FIG. 4, the data R1 being read out at the ordinary read voltage V1 and the data R2 being read out at the defect detecting read voltage V2 are mismatched. Therefore, the error flag generating circuit 11 generates an error flag, and the address mismatched at the rise of this error flag, that is, the address taken into the address latch circuit 7 at the timing of φ3 is stored in the address latch circuit 9. On the other hand, the data R1 taken into the data latch circuit 8 having a correct address value is stored in the data latch circuit 10. Further, by using the error flag as an interrupt signal, the CPU 3 recognizes the error, and issues the address read signal and data read signal, and reads out the mismatched addresses stored in the address latch circuit 9 and data latch circuit 10, and the data R1 having the correct address, then writes the correct data again in the mismatched address.

In the embodiment having such configuration, the microcomputer incorporating the FLASH EEPROM 6 comprises the read voltage generating circuit 2 for generating the defect detecting voltage V2 of higher voltage than the data read voltage V1 of the FLASH EEPROM 6, and the comparator 5 for comparing the data being read out at respective voltages, so that a read error can be detected by the CPU 3 itself. Accordingly, if the threshold voltage of the written cell declines with the passing of the time, before becoming lower than the read voltage V1, its address is detected beforehand, so that malfunction of the microcomputer due to reading of wrong data can be prevented.

The mismatched address and correct data being read out at ordinary read voltage are held in the reading defect detecting circuit of the FLASH EEPROM 6. Therefore, in the FLASH EEPROM 6 reading out the mismatched data R1 and data R2, the address and data R1 having the correct data are read out, and the correct data R1 is written again, so that the threshold voltage can be increased.

What is claimed is:

1. A reading defect detecting circuit of EEPROM comprising:
an ordinary read voltage generating circuit for generating a voltage to be used in ordinary reading of EEPROM which is the object of detection,
a defect detecting read voltage generating circuit for generating a defect detecting read voltage which is higher than the ordinary read voltage,
a selector for selecting a voltage to be applied to the EEPROM from the ordinary read voltage and defect detecting read voltage,
a control circuit for controlling the selection timing of this selector, and
a comparator for comparing first data and second data being read out by said EEPROM from the ordinary read voltage and defect detecting read voltage respectively selected by said selector.

2. The reading defect detecting circuit of EEPROM of claim 1, wherein said comparator includes an error flag generating circuit for generating an error flag when the first data and second data are not matched.

3. The reading defect detecting circuit of EEPROM of claim 1, wherein said comparator includes a data latch circuit and an address latch circuit for storing respectively the first data and its address in the EEPROM.

4. The reading defect detecting circuit of EEPROM of claim 1, wherein it is at least designed to repeat a period composed of a first timing for selecting the ordinary read voltage by said selector, a second timing for selecting the defect detecting read voltage by said selector, and a third timing for comparing the first and second data by said comparator.

5. The reading defect detecting circuit of EEPROM of claim 2, wherein said comparator includes a data latch circuit and an address latch circuit for storing respectively the first data and its address in the EEPROM.

6. The reading defect detecting circuit of EEPROM of claim 2, wherein it is at least designed to repeat a period composed of a first timing for selecting the ordinary read voltage by said selector, a second timing for selecting the defect detecting read voltage by said selector, and a third timing for comparing the first and second data by said comparator.

7. The reading defect detecting circuit of EEPROM of claim 3, wherein it is designed to repeat a period comprising at least a first timing for selecting the ordinary read voltage by said selector, a second timing for selecting the defect detecting read voltage by said selector, and a third timing for comparing the first and second data by said comparator.

8. A reading defect detecting method of EEPROM comprising the steps of:
reading out first data and second data respectively by applying an ordinary read voltage used as ordinary read voltage of EEPROM to be detected and a defect detecting read voltage higher than this ordinary read voltage sequentially into said EEPROM,
comparing the first data and second data, and
generating an error flag when the first data and second data are not matched at the comparing step.

9. The reading defect detecting method of EEPROM of claim 8, wherein, after an error flag is generated, the first data is written at the address in the EEPROM from which the first data and second data are read out.
